(19) United States
(12) Patent Application Publication
(10) Pub. No.: US 2022/0375905 A1
(43) Pub. Date: Nov. 24, 2022

(54) DETUNED ANTINODE ENHANCEMENT FOR IMPROVED TEMPERATURE INDEPENDENCE IN INFRARED LIGHT EMITTING DIODES

(71) Applicants: Joseph D LaVeigne, Buellton, CA (US); Thomas E Danielson, Santa Barbara, CA (US); Igor Vurgaftman, Severna Park, MD (US); Chadwick L Canedy, Washington, DC (US); Mijin Kim, West Springfield, VA (US); Chul Soo Kim, West Springfield, VA (US); William W Bewley, Falls Church, VA (US); Charles D Merritt, Faifax, VY (US); Jerry R Meyer, Catonsville, MD (US)

(72) Inventors: Joseph D LaVeigne, Buellton, CA (US); Thomas E Danielson, Santa Barbara, CA (US); Igor Vurgaftman, Severna Park, MD (US); Chadwick L Canedy, Washington, DC (US); Mijin Kim, West Springfield, VA (US); Chul Soo Kim, West Springfield, VA (US); William W Bewley, Falls Church, VA (US); Charles D Merritt, Faifax, VY (US); Jerry R Meyer, Catonsville, MD (US)

(21) Appl. No.: 17/740,387

(22) Filed: May 10, 2022

Related U.S. Application Data
(60) Provisional application No. 63/186,223, filed on May 10, 2021.

(51) Int. Cl. H01L 25/075; G03B 21/20

(52) U.S. Cl. CPC H01L 25/0753; G03B 21/2033

(57) ABSTRACT

Improved temperature independence in infrared light emitting diodes (IRLEDs). The active stage groups (ASGs) occur at or at an integer multiple of each antinode of the e-field of the desired center wavelength. The structure is designed to yield increased efficiency at low (cryogenic) temperatures with a wide range of operational temperature independence. The structure may be designed to provide a wide range of temperature independent operation near room temperature. The spacing (S) between the centers of the active stage groups may be varied to create a more broad and shallow peak of the temperature dependence of the antinode enhancement. The IRLED may be an interband cascade LED. A plurality (or array) of IRLEDs may be used in an infrared scene projector (IRSP)

### CROSS-REFERENCE TO RELATED APPLICATIONS

This is a nonprovisional filing of 63/186,223 filed 10 May 2021, incorporated by reference herein.

### TECHNICAL FIELD

This disclosure relates to LEDs (Light Emitting Diodes) and, more particularly, to IR LEDs (Infrared Light Emitting Diodes). Generally speaking, an IR LED is a device that emits light with a wavelength which is the infrared range of electromagnetic radiation spectrum. The wavelength range extends from 760 nm (nanometers) to 20 μm (microns).

### BACKGROUND

A light-emitting diode (LED) is a semiconductor light source that emits light when current flows through it. Electrons in the semiconductor recombine with electron holes, releasing energy in the form of photons. The color of the light (corresponding to the energy of the photons) is determined by the energy required for electrons to cross the band gap of the semiconductor.

In a light emitting diode (LED), the recombination of electrons and electron holes in a semiconductor produces light (be it infrared, visible or UV), a process called “electroluminescence”. The wavelength of the light depends on the energy band gap of the semiconductors used. Since these materials have a high index of refraction, design features of the devices such as special optical coatings and die shape are required to efficiently emit light.

U.S. Pat. No. 3,293,513 (1966 Dec. 20; Biard et al.) discloses a gallium-arsenide diode that radiates electromagnetic energy having a band of wavelengths in the near infrared spectrum when the junction of the diode is forward-biased.

### IRLEDs

Infrared light emitting diodes (IRLEDs or ILEDs) are interesting as sources for a number of applications. For some applications, such as a source for a spectrometer, maximum output at the nominal operating temperature is desirable. For others, such as for a source for an infrared scene projector (IRSP) used in hardware-in-the-loop (HWIL, or HITL) testing, temperature independence is a very desirable feature.

IRLEDs for an IRSP are often operated at cryogenic temperatures with the boiling point of liquid nitrogen (LN2) at 77K being a common temperature for operation and testing. At room temperature, (˜300K), IRLEDs have reduced efficiency due to non-radiative losses in the LED. One of the primary losses is Auger recombination, which is a process in which the momentum of a carrier (electron/hole) is transferred to a third carrier instead of creating a photon. The magnitude of the recombination is proportional to the carrier concentration cubed. Carrier concentration is reduced as temperature decreases, resulting in much higher efficiency at cryogenic temperature. The magnitude of the increase is proportional to T^{-(3/2}). This leads to ˜7.5× increase in output with a temperature change from 300K to 77K.

While the aforementioned improved efficiency is desirable, the temperature dependence can lead to operational difficulties in an IRSP application. IRLEDs do not have high efficiencies, and most of the power applied to them is lost as waste heat. For a typical IRSP application, individual pixels may have a pitch on the order of 24 μm and require >30 mW per pixel to achieve their maximum desired output. Removing this much power from the LED is not an issue for a small number of pixels. However, as the number of high-power pixels grows, the heat cannot be removed quickly and significant increases in the emitter (i.e., the diode) temperature can occur. As the emitter heats, its efficiency drops dramatically, resulting in a decrease in output of over 20% for a 40K rise in substrate temperature. This magnitude of temperature increase can be seen with very modest hotspots. Consider that a 100×100 pixel area would subtend (cover) an area of 2.4×2.4 mm and would need to dissipate >300 W, thus leading to a power density over 5 kW/cm2. Even with a high thermal conductivity substrate, such as aluminum nitride with thermal conductivity >1000 Wm-1K-1, such a power density would result in a substrate temperature rise of 10's of degrees (° C.). Such a significant change in output efficiency negatively affects the output accuracy of the emitter arrays where radiometric accuracy on the order of 1% is desired. Furthermore, a large hotspot can start to affect neighboring pixels, leading to a significant problem where the output of a given pixel may strongly depend on how other pixels are being driven. To address these issues, a method of reducing the amount of temperature dependence over the operational temperature range of the emitter system is desirable.

One type of IRLED being investigated for IRSP use is an interband cascade LED (ICLED). ICLEDs use proximate wells to confine electrons and holes generating a gap between wells. This is compared to a more classic quantum well that has electron and holes confined in conduction and valence bands in the same well.

See references [1]-[4], incorporated by reference herein, for a selection of papers describing ICLEDs and related devices.
[1] M. Kim et al., “Interband Cascade Laser Emitting at =3.75 m in Continuous Wave above Room Temperature,” Appl. Phys. Lett, vol. 92, 2008.
[2] M. Kim et al., “High-Power Continuous-Wave Interband Cascade Lasers with 10 Active Stages,” Opt. Expr., vol. 23, no. 8, 2015.
[3] W. W. Bewley et al., “High-Power Room-Temperature Continuous-Wave Mid-Infrared Interband Cascade Lasers,” Opt. Expr., vol. 20, 2012.
[4] J Abell et al., “Mid-infrared interband cascade light emitting devices with milliwatt output powers at room temperature,” Applied Physics Letters, vol. 104, no. 26, June 2014.

Reference is also made to Improved mid-infrared interband cascade light-emitting devices; Chul Soo Kim, William W. Bewley, Charles D. Merritt, Chad L. Canedy, Michael V. Warren, † Igor Vurgaftman, Jerry R. Meyer, and Mijin Kim; Optical Engineering 57(1), 011002 (January 2018), incorporated by reference herein.

Reference is also made to Mid-infrared interband cascade light emitting devices grown on off-axis silicon substrates, Canedy et al.; Optics Express, Vol. 29, Issue 22, 2021, 19 pages, incorporated by reference herein.

### SUMMARY

It is an object of the invention to provide improved techniques for designing, making and using IRLEDs, such as may be used in an array of IRLEDs for an infrared scene projector (IRSP).

It is an object of the invention to provide an improved structure for an IRLED with reduced temperature dependence by designing the structure such that enhancement due to locating the active region at center wavelength antinodes is lost, while subsequent gains are realized in radiative efficiency due to other thermal effects. The IRLED may be an interband cascade LED. The structure is designed to yield increased efficiency at low (cryogenic) temperatures with a wide range of operational temperature independence. Active stages may be grouped such that the active stage groups (ASGs) occur: (i) at each antinode of the e-field of the desired center wavelength, or (ii) at an integer or more than one integer multiple of the antinodes of the e-field of the desired center wavelength. The structure is designed to provide a wide range of temperature independent operation near room temperature. The spacing the centers of the active groups may be varied to create a more broad and shallow peak of the temperature dependence of the antinode enhancement.

According to the invention, generally, improved temperature independence in infrared light emitting diodes (IRLEDs). The active stage groups (ASGs) occur at or at an integer multiple of each antinode of the e-field of the desired center wavelength. The structure is designed to yield increased efficiency at low (cryogenic) temperatures with a wide range of operational temperature independence. The structure may be designed to provide a wide range of temperature independent operation near room temperature. The spacing (S) between the centers of the active stage groups may be varied to create a more broad and shallow peak of the temperature dependence of the antinode enhancement. The IRLED may be an interband cascade LED. A plurality (or array) of IRLEDs may be used in an infrared scene projector (IRSP).

According to an embodiment (example) of the invention, a method of improving temperature independence of an infrared light emitting diode (IRLED) may comprise: designing the structure or the IRLED such that enhancement due to locating the active region (groups of active stages, AGS) at center wavelength antinodes decreases while subsequent gains are realized in radiative efficiency due to other thermal effects. The IRLED may be an interband cascade LED.

The structure may be designed to yield increased efficiency at low (cryogenic) temperatures with a wide range of operational temperature independence.

The active stage groups may be designed to occur (be positioned) at each antinode of the e-field of the desired center wavelength, or at an integer multiple of the antinodes of the e-field of the desired center wavelength, or at more than one integer multiple of the antinodes of the e-field of the desired center wavelength.

The structure may be designed to provide a wide range of temperature independent operation near room temperature.

The spacing between the centers of the active groups may be varied to create a more broad and shallow peak of the temperature dependence of the antinode enhancement.

According to an embodiment (example) of the invention, an infrared light-emitting diode (IRLED) may comprise: a stackup or buildup of a number of active stage groups (ASGs) separated by spacers (S), wherein: the spacing between ASGs is designed to be in phase with antinodes at a relatively high temperature and out of phase at a relatively low temperature where each stage ASG has a higher efficiency, by selecting spacers to achieve more temperature independence. The relatively high temperature may be higher, such as 50 or more degrees higher than the operating temperature of the IRLED, including room temperature The relatively low temperature may a cryogenic temperature. The spacers may all be the same size (thickness) as one another. some of the spaces have a thickness which is an integer multiple of the thickness of some other of the spacers. The IRLED may be an interband cascade LED.

According to an embodiment (example) of the invention, an infrared scene projector (IRSP) may comprise a plurality of IRLEDs, such as described herein, having improved temperature independence.

According to some features of the invention,
the antinode spacing is designed and set up to provide a peak at a particular temp, combined with minimal temperature dependence. This enhancement (improvement in efficiency) occurs if the group spacing is approximately the in-medium wavelength of the LED;
purposely detuning of the antinode enhancement can counteract the increase in efficiency with lower temperature, making the LED output much less temperature dependent; and.
a way to reduce the temperature dependence is to design the antinode enhancement such that it is optimized at a temperature above the operational temperature of the device. With this optimization, increased losses due to nonradiative recombination as the temperature increases may be offset by gains from the antinode enhancement until the temperature of the antinode peak is reached.

Other objects, features and advantages of the invention may become apparent from the following description of various embodiments of the invention.

### BRIEF DESCRIPTION OF THE DRAWINGS

Reference will be made in detail to embodiments of the disclosure, non-limiting examples of which may be illustrated in the accompanying drawing figures (FIGs). The figures may generally be in the form of diagrams. Some elements in the figures may be stylized, simplified or exaggerated, others may be omitted, for illustrative clarity.

Although the invention is generally described in the context of various exemplary embodiments, it should be understood that it is not intended to limit the invention to these particular embodiments, and individual features of various embodiments may be combined with one another. Any text (legends, notes, reference numerals and the like) appearing on the drawings are incorporated by reference herein.

Some elements may be referred to with letters or abbreviations (“LED”, ASn, BC, TC, Sn, etc.) rather than or in addition to numerals. Some similar (including substantially identical) elements in various embodiments may be similarly numbered, with a given numeral such as “310”, followed by different letters such as “A”, “B”, “C”, etc. (resulting in “310A”, “310B”, “310C”), and may collectively (all of them at once) referred to simply by the numeral (“310”).

FIG. 1 is a diagram (cross-sectional view) illustrating a design of an IRLED with antinode enhancement optimized for 3.5 μm output, according to an embodiment of the invention.

FIG. 2 is a diagram (cross-sectional view) illustrating a design of an IRLED with multiple-integer antinode spacing in an area for increased temperature dependence of the antinode enhancement, according to an embodiment of the invention.

FIG. 3 is a graph illustrating IRLED temperature dependence for a design optimized for operation at room temperature (300K).

FIG. 4 is a graph illustrating IRLED temperature dependence for a design optimized for operation at cryogenic temperature (77K).

FIG. 5 is a graph illustrating IRLED temperature dependence for a design optimized for temperature independent operation from 75K to 125K.

### DETAILED DESCRIPTION

Various embodiments (or examples) may be described to illustrate teachings of the invention(s), and should be construed as illustrative rather than limiting. It should be understood that it is not intended to limit the invention(s) to these particular embodiments. It should be understood that some individual features of various embodiments may be combined in different ways than shown, with one another. Reference herein to “one embodiment”, “an embodiment”, or similar formulations, may mean that a particular feature, structure, operation, or characteristic described in connection with the embodiment is included in at least one embodiment of the present invention. Some embodiments may not be explicitly designated as such (“an embodiment”).

The embodiments and aspects thereof may be described and illustrated in conjunction with systems, devices and methods which are meant to be exemplary and illustrative, not limiting in scope. Specific configurations and details may be set forth in order to provide an understanding of the invention(s). However, it should be apparent to one skilled in the art that the invention(s) may be practiced without some of the specific details being presented herein.

Furthermore, some well-known steps or components may be described only generally, or even omitted, for the sake of illustrative clarity. Elements referred to in the singular (e.g., “a widget”) may be interpreted to include the possibility of plural instances of the element (e.g., “at least one widget”), unless explicitly otherwise stated (e.g., “one and only one widget”).

In the following descriptions, some specific details may be set forth in order to provide an understanding of the invention(s) disclosed herein. It should be apparent to those skilled in the art that these invention(s) may be practiced without these specific details. Any dimensions and materials or processes set forth herein should be considered to be approximate and exemplary, unless otherwise indicated. Headings (typically underlined) may be provided as an aid to the reader, and should not be construed as limiting.

Reference may be made to disclosures of prior patents, publications and applications. Some text and drawings from those sources may be presented herein, but may be modified, edited or commented to blend more smoothly with the disclosure of the present application.

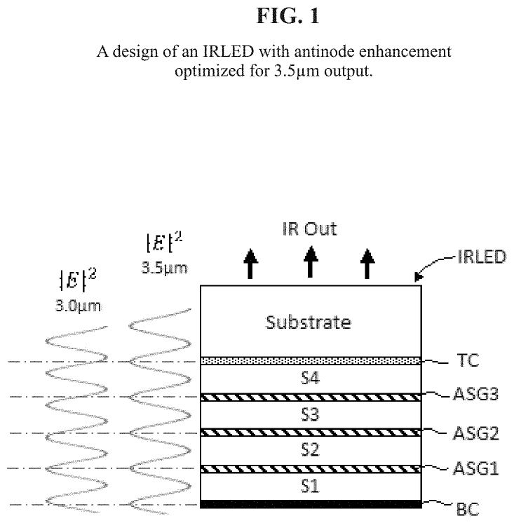

Generally, IRLEDs may be designed for a different (higher) temperature than they are going to operate (e.g., in an IRSP, operating at cryogenic temperatures). Although gain may decrease by operating at a different (than design) temperature, gain may increase at the lower (e.g., cryogenic) temperature. Wells may be spaced ½ wavelength apart. An exemplary design is shown at FIG. 1.

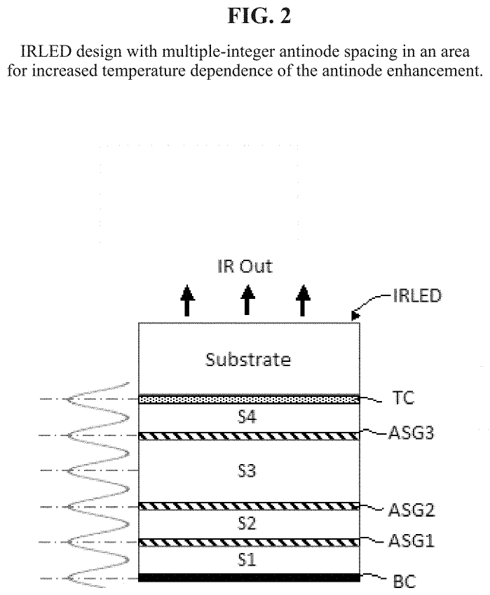

It has been determined that although there may be little or no net increase in gain from the room temperature optimized design, when operating at cryogenic temperatures (e.g., 77K), it has been observed that there is less temperature dependence, the response curve being flatter, and allowing reasonable (e.g., +/−20K) variations in temperature while performing to specification. Refer to FIG. 2

Individual active emitting areas of IRLEDs require very low voltages to operate, typically less than 0.5V. A known method to bring the operational voltage up to a more common voltage is to “stack” individual emitting stages so they operate in series. This method of stacking the LEDs essentially trades voltage for current and allows the LED to be optimized to work with a desired driver circuit.

As is known, improved efficiency (an output which is high and consistent) in ICLEDs may be achieved, such as for operation near room temperature, by grouping (stacking) a plurality active stages and placing (disposing, locating) them at the antinodes of the optical field with spacer material between the active areas. In other words, grouping the active stages and placing them at the antinodes of the optical field may improve the efficiency of ICLEDs, at room temperature.

According to a feature of the invention, the antinode spacing is designed and set up to provide a peak at a particular temp, combined with minimal temperature dependence. This enhancement (improvement in efficiency) occurs if the group spacing is approximately the in-medium wavelength of the LED. For example, GaSb (Gallium-Antimony), a common substrate material, has an index of refraction near 3.5 for midwave IR wavelengths (3-5 μm). The in-medium wavelength of a 3.5 μm emitter would be approximately 1 μm. The antinodes occur at the points of highest magnitude of the E-field, with two peaks per full cycle of the wavelength. Therefore, in this example, active areas for the enhancement may be placed every 500 nm in the structure and the first active area centered 500 nm from the contact in order to achieve the maximum output enhancement.

A 15-stage device might have three groups (GR) of five stages (ASG) and have an overall thickness of approximately 1500 nm.

As is known, LED wavelength changes with temperature as the electronic structure of the various doped layers changes. For ICLEDs, this wavelength change can be up to 20%, with an LED that has a center wavelength of 3.5 μm at room temperature (300K), shifting (decreasing) to 3.0 μm at 77° K. A wavelength change of this magnitude can remove most of any enhancement due to the spacing of the active stages, if they were optimized for a 3.5 μm center wavelength.

According to an aspect of the invention, generally, purposely detuning of the antinode enhancement can counteract the increase in efficiency with lower temperature, making the LED output much less temperature dependent. More particularly, for maximum output efficiency the antinode spacing may be engineered such that it is substantially exactly in tune with the center wavelength at the desired operational temperature of the device. However, this maximum-efficiency design would also exhibit large temperature dependence, as any increase in temperature would lead to losses from detuning of the antinode enhancement as well as normal efficiency losses in the emitter itself due to increased nonradiative recombination.

According to an aspect of the invention, a way to reduce the temperature dependence is to design the antinode enhancement such that it is optimized at a temperature above the operational temperature of the device. With this optimization, increased losses due to nonradiative recombination as the temperature increases may be offset by gains from the antinode enhancement until the temperature of the antinode peak is reached.

According to an aspect of the invention, the temperature dependence of the antinode enhancement can be influenced by adjusting the total spacing between the active stages of the device. A larger total spacing between the active device will be more sensitive to shifts in the center wavelength. For example, fewer stages can be grouped together at each active region such that the overall region is larger. An exemplary 15-stage device could be changed (arranged) to have five groups of three stages in each group, and be approximately 2500 nm thick and exhibit greater temperature dependence. The centers of adjacent groups may be separated by 500 nm from each other.

Another option is to locate the stages at multiple integer steps of the antinode peaks. Again, the exemplary 15-stage device could use 1000 nm spacing and the three groups of five stages would then result in a 3000 nm thick device with greater temperature dependence as well.

The stage groupings (groupings of adjacent active stages) does not need to be equal. For example, a 15-stage (i.e., stackup of 15 active stage groups, ASG1, ASG2 . . . ASG15) device might comprise a group of 4 stages, a group of 5 stages, and a group of 8 stages.

The spacings, as defined/established by spacers (S1, S2 . . . Sn) between individual, adjacent stages need not be equal (uniform). Fine adjustment of the temperature dependence of the IRLED device (emitter) may be achieved by having some spacings larger than others. For example, a 15-stage device might have one or more grouping of active stages separated from one another (i.e., from adjacent active stages within the grouping) by a 500 nm thick spacer, and another grouping of active stages separated from one another (i.e., from adjacent active stages within the grouping) by a 1000 nm thick spacer, in order to attain temperature dependence equal to that of an IRLED having a uniform 500 nm or 1000 nm spacing. An example of such a design can be seen in FIG. 2.

Furthermore, the temperature dependence peak might be softened (flattened) by purposefully introducing variations in the spacing. For example, another modification of the exemplary 15-stage device might have: the first stage grouping spaced at 490 nm; the second stage grouping spaced at 500 nm; and the third stage grouping spaced at 510 nm to create a lower, broader peak in the antinode enhancement.

### An Embodiment

FIG. 1 is a diagram illustrating an embodiment of a design for an IRLED with antinode enhancement optimized for 3.5 μm output.

In this example, the active stages of the IRLED are spaced at antinodes for its room temperature center wavelength of 3.5 μm. (Active stages grouped for 3.5 μm center wavelength.)

More particularly, this figure shows the following elements (from bottom to top):

A construction of an infrared light-emitting diode (IRLED) device having three (3) active stage groups (ASG1, ASG2, ASG3) may comprise:
a bottom contact (BC), comprising a metal material such as silver or gold, having a thickness of approximately a few hundred Angstroms;
a first spacer (S1) disposed on the bottom metal contact, comprising a material such as GaSb (Gallium-Antimony), having a thickness of approximately 400 nm;
a first active stage (ASG1) having a quantum well disposed on the bottom metal contact, comprising doped GaSb having a thickness of approximately 100 nm;
a second spacer (S2) disposed on the first active stage, having a thickness equal to the thickness of the first spacer (S1);
a second active stage (ASG2), similar or substantially identical to the first active stage (ASG1), disposed on the second spacer;
a third spacer (S3) disposed on the second active stage, having a thickness equal to the thickness of the first and second spacers (S1, S2);
a third active stage (ASG3), similar or substantially identical to the first and second active stages (ASG1, ASG2), disposed on the third spacer;
a fourth spacer (S4) disposed on the third active stage (ASG3), having a thickness equal to the thickness of the first, second, and third spacers (S1, S2, S3); and
a top contact (TC), comprising a conductive material, transparent to IR, such as doped GaSb, having a thickness of approximately a few hundred Angstroms, disposed on the fourth spacer (S4).

In this example, the thicknesses of all four spacers (S1, S2, S3, S4) are shown as being the same as one another. In the embodiment of FIG. 2, the thickness of the spaces may be different than one another.

The thicknesses of the three active stage groups (ASG1, ASG2, ASG3) may all be the same as one another, or they may be different than one another.

As used herein, the term “active stage” may refer to a group of active stages, or “active stage group”.

A substrate (“Substrate”), comprising a material such as GaSb, having an exemplary initial thickness of approximately 1 or 2 mm, thinned down to approx 100 μm, is shown disposed on the top contact (TC). The substrate is be transparent to the IR coming from the LED device (emitter).

The total exemplary thickness of the active stages (ASG) and spacers (S) in the IRLED device may be 2500 nm (2.5 μm) or 3000 nm (3.5 μm), as discussed in some of the examples set forth herein.

The materials and thicknesses set forth herein are exemplary, it being within the purview of a person having ordinary skill in the art to tailor the materials and thicknesses to specific applications, based on the teachings set forth herein (and in the prior art).

The vertical arrows situated on top of the IRLED indicates the infrared output (IR Out) of the emitter (LED).

The sinusoids shown to the left of the IRLED depict the magnitude of the E-field for wavelengths of 3.5 μm and 3.0 μm. The dashed horizontal lines extending (to the left) from the centers of the active stages (ASG1, ASG2, ASG3) show the design is in-tune (optimized) for 3.5 μm output (such as at a relatively high temperature, such as room temperature), but out-of-tune for 3.0 μm output (such as at a relatively low, cryogenic temperature). In other words, the active stages of the IRLED may be grouped at antinodes of the optical field for a 3.5 μm center wavelength. For 3.5 μm (wavelength) output, the design matches the output and enhancement structure are in sync (and the output may be boosted), while they are not in sync for 3.0 um output (but may exhibit improved temperature independence).

In the embodiment illustrated in FIG. 1, the groups of active stages (ASG) are disposed at regular, even spacings relative to the antinodes.

In the embodiment shown in the next figure (FIG. 2), the active stages (or active stage groups) are disposed at irregular, non-even, multiple-integer intervals relative to the antinodes.

### Another Embodiment

FIG. 2 is a diagram illustrating a design of an IRLED with multiple-integer antinode spacing in an area for increased temperature dependence of the antinode enhancement.

In this example, the active stages of the IRLED are spaced at antinodes for a room temperature center wavelength of 3.5 μm. (Active stages grouped for 3.5 μm center wavelength.)

More particularly, FIG. 2 shows the following elements (from bottom to top):

A construction of an infrared light-emitting diode (IRLED) device having three (3) active stage groups (ASG1, ASG2, ASG3) may comprise:
a bottom contact (BC), comprising a metal material such as silver or gold, having a thickness of approximately a few hundred Angstroms; (may be the same as in FIG. 1)
a first spacer (S1) disposed on the bottom metal contact, comprising a material such as GaSb (Gallium-Antimony), having a thickness of approximately 400 nm; (may be the same as in FIG. 1)
a first active stage group (ASG1) having a quantum well disposed on the bottom metal contact, comprising doped GaSb having a thickness of approximately 100 nm; (may be the same as in FIG. 1)
a second spacer (S2) disposed on the first active stage, having a thickness equal to the thickness of the first spacer (S1) (same as in FIG. 1);
a second active stage group (ASG2) disposed on the second spacer; (may be the same as in FIG. 1)
a third spacer (S3) disposed on the second active stage having a thickness which is a whole number (integer) multiple of the thickness of the first or second spacers (S1, S2), such as 800 nm (2×400 nm), 1200 nm (3×400 nm), etc; (different than in FIG. 1)
a third active stage group (ASG3) disposed on the third spacer; (may be the same as in FIG. 1)
a fourth spacer (S4) disposed on the third active stage (ASG3), having a thickness which may be equal to the thickness of the first and second spacers (S1, S2); (may be the same as in FIG. 1)
a top contact (TC), comprising a conductive material, transparent to IR, such as doped GaSb, having a thickness of approximately a few hundred Angstroms disposed on the fourth spacer (S4); (may be the same as in FIG. 1)

In this example, it is illustrated that the thicknesses of the four spacers (S1, S2, S3, S4) may be different than one another. A subset of the spacers may all have the same thickness, with at least one having a different thickness than the others.

The thicknesses of the three active stage groups (ASG1, ASG2, ASG3) may all be the same as one another, or they may be different than one another.

A substrate (“Substrate”), comprising a material such as GaSb, having an exemplary initial thickness of approximately 1 or 2 mm, thinned down to approx 100 μm, is shown disposed on the top contact (TC). The substrate is be transparent to the IR coming from the LED device (emitter). (may be the same as in FIG. 1)

The total exemplary thickness of the active stages (ASG) and spacers (S) in the IRLED device may be 2500 nm (2.5 μm) or 3000 nm (3.5 μm), as discussed in some of the examples set forth herein.

The vertical arrows situated on top of the IRLED indicates the infrared output (IR Out) of the emitter (LED).

The sinusoids shown to the left of the IRLED depict the magnitude of the E-field for wavelengths of 3.5 μm and 3.0 μm. The dashed horizontal lines extending (to the left) from the centers of the active stages (ASG1, ASG2, ASG3) show the design is in-tune (optimized) for 3.5 μm output, but out-of-tune for 3.0 μm output. In other words, the active stages of the IRLED may be grouped at antinodes of the optical field for a 3.5 μm center wavelength. For 3.5 μm (wavelength) output, the design matches the output and enhancement structure are in sync, while they are not in sync for 3.0 um output.

### Temperature Dependence

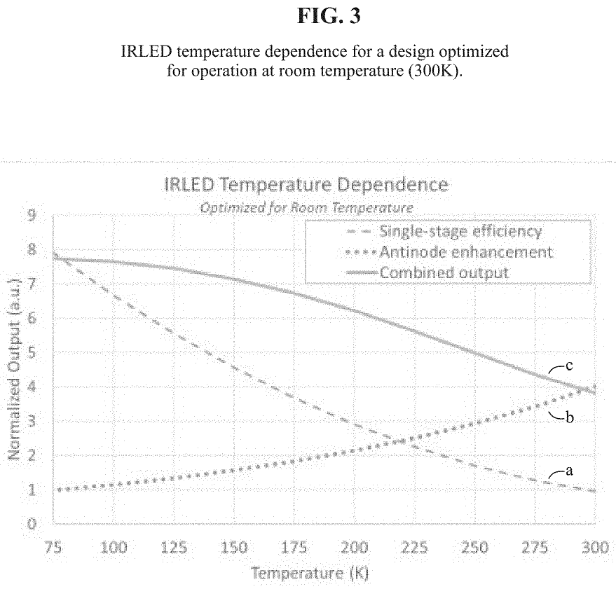

FIG. 3 is a graph illustrating IRLED temperature dependence for a design (with antinode enhancement) optimized for operation at room temperature (300K).

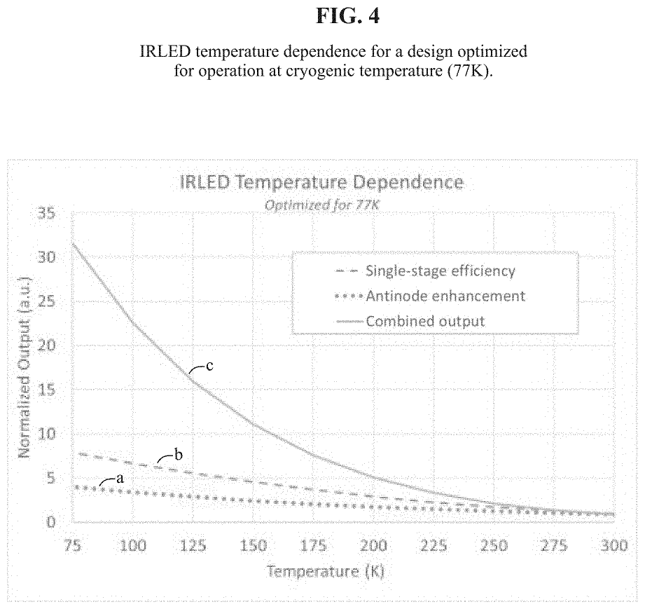

FIG. 4 is a graph illustrating IRLED temperature dependence for a design optimized for operation at cryogenic temperature (77K).

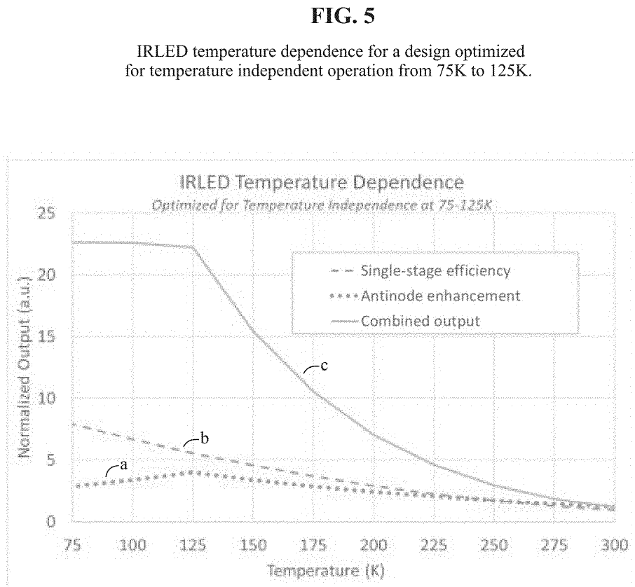

FIG. 5 is a graph illustrating IRLED temperature dependence for a design optimized for temperature independent operation from 75K to 125K.

The following lines (traces, curves) are shown in FIGS. 3,4,5:
a. Single-stage efficiency
b. Antinode enhancement
c. Combined LED output

In all three graphs, IRLED normalized output is shown decreasing with increased temperature (conversely, increasing with decreasing temperature).

FIG. 3 shows IRLED Output Change with Temperature, and illustrates that IRLED efficiency increases with decreasing temperature. As the temperature decreases, the efficiency of the stages increases as nonradiative losses are reduced. At the same time, the center wavelength moves off of the optimal, room temperature value, causing a decrease in the enhancement due to antinode positioning of the active emitter stages. This loss in efficiency partially counters the gains from improved radiative efficiency, leading to an IRLED with reduced temperature dependence.

FIG. 4 is a graph showing IRLED temperature dependence for a design optimized for operation at cryogenic temperature (77K).

FIG. 4 shows IRLED Output Change with Temperature, for a design with the antinode enhancement optimized for the wavelength at 77K. As the temperature decreases, the efficiency of the stages increases as nonradiative losses are reduced. At the same time, the center wavelength moves towards the optimal, room temperature value, causing an increase in the enhancement due to antinode positioning of the active emitter stages. These two gains combine to yield a large increase in efficiency at 77K, but with very significant temperature dependence.

FIG. 5 is a graph showing IRLED temperature dependence for a design optimized for temperature independent operation from 75K to 125K.

FIG. 5 shows IRLED Output Change with Temperature, for a design with the antinode enhancement optimized for temperature dependent operation between 75K and 125K. As the temperature decreases, the efficiency of the stages increases as nonradiative losses are reduced. At the same time, the center wavelength moves through optimum at 125K, causing a peak in the enhancement due to antinode positioning of the active emitter stages at 125K, followed by a reduction in the enhancement at lower temperatures. These two gains combine to yield a significant increase in efficiency with a broad operational range with limited temperature dependence. (The curve “c” is substantially flat between 75K and 125K.)

A plurality (or array) of infrared light-emitting diodes (IRLEDs), such as described herein, may advantageously be used in an infrared scene projector (IRSP), such as mentioned above.

While the invention(s) may have been described with respect to a limited number of embodiments, these should not be construed as limitations on the scope of the invention(s), but rather as examples of some of the embodiments of the invention(s). Those skilled in the art may envision other possible variations, modifications, and implementations that are also within the scope of the invention(s), and claims, based on the disclosure(s) set forth herein.

What is claimed is:

1. A method of improving temperature independence of an infrared light emitting diode (IRLED), comprising:
designing the structure of the IRLED such that enhancement due to locating the active region (groups of active stages, AGS) at center wavelength antinodes decreases while subsequent gains are realized in radiative efficiency due to other thermal effects.

2. The method of claim 1, wherein:
the IRLED is an interband cascade LED.

3. The method of claim 1, wherein:
the structure is designed to yield increased efficiency at low (cryogenic) temperatures with a wide range of operational temperature independence.

4. The method of claim 1, wherein:
the active stage groups occur at each antinode of the e-field of the desired center wavelength.

5. The method of claim 1, wherein:
the active stage groups occur at an integer multiple of the antinodes of the e-field of the desired center wavelength.

6. The method of claim 1, wherein:
the active stage groups occur at more than one integer multiple of the antinodes of the e-field of the desired center wavelength.

7. The method of claim 1, wherein:
the structure is designed to provide a wide range of temperature independent operation near room temperature.

8. The method of claim 1, wherein:
the spacing between the centers of the active groups are varied to create a more broad and shallow peak of the temperature dependence of the antinode enhancement.

9. An infrared light-emitting diode (IRLED), comprising:
a number of active stage groups (ASGs) separated by spacers (S), wherein:
the spacing between ASGs is designed to be in phase with antinodes at a relatively high temperature and out of phase at a relatively low temperature where each stage ASG has a higher efficiency, by selecting spacers to achieve more temperature independence.

10. The IRLED of claim 9, wherein:
the relatively high temperature is higher than the operating temperature of the IRLED; and
the relatively low temperature is a cryogenic temperature.

11. The IRLED of claim 9, wherein:
the spacers are all same size (thickness) as one another.

12. The IRLED of claim 9, wherein:
some of the spaces have a thickness which is an integer multiple of the thickness of some other of the spacers.

13. The IRLED of claim 1, wherein:
the IRLED is an interband cascade LED.

14. An infrared scene projector (IRSP) comprising a plurality of IRLEDs described in claim 9.
